(19) United States
(12) Patent Application Publication
(10) Pub. No.: US 2025/0040038 A1
(43) Pub. Date: Jan. 30, 2025

(54) ELECTRONIC DEVICE INCLUDING PRINTED CIRCUIT BOARD

(71) Applicant: SAMSUNG ELECTRONICS CO., LTD., Suwon-si (KR)

(72) Inventors: Minseok LEE, Suwon-si (KR); Sujung KIM, Suwon-si (KR); Myungkyoon CHUNG, Suwon-si (KR)

(73) Assignee: SAMSUNG ELECTRONICS CO., LTD., Suwon-si (KR)

(21) Appl. No.: 18/782,938

(22) Filed: Jul. 24, 2024

Related U.S. Application Data
(63) Continuation of application No. PCT/KR2024/010361, filed on Jul. 18, 2024.

(30) Foreign Application Priority Data
Jul. 24, 2023 (KR) 10-2023-0096368
Nov. 1, 2023 (KR) 10-2023-0149050

(51) Int. Cl. H05K 1/02; H05K 1/11; H05K 1/18

(52) U.S. Cl. CPC H05K 1/0271; H05K 1/111; H05K 1/181; H05K 2201/10015; H05K 2201/2045

(57) ABSTRACT

An electronic device may include: a printed circuit board; and a capacitor disposed on the printed circuit board. The printed circuit board may include: a conductive layer including at least one slit in an area adjacent to the capacitor, and an insulation layer directly on the conductive layer and including a portion in the at least one slit. The at least one slit may be parallel to at least one side surface of the capacitor, and spaced apart from the at least one side surface of the capacitor by a first distance or less. The at least one slit may not overlap the capacitor when viewed from above.

### CROSS-REFERENCE TO RELATED APPLICATION(S)

This application is a continuation application, claiming priority under § 365 (c), of an International application No. PCT/KR2024/010361, filed on Jul. 18, 2024, which is based on and claims the benefit of a Korean patent application number 10-2023-0096368, filed on Jul. 24, 2023, in the Korean Intellectual Property Office, and of a Korean patent application number 10-2023-0149050, filed on Nov. 1, 2023, in the Korean Intellectual Property Office, the disclosure of each of which is incorporated by reference herein in its entirety.

### BACKGROUND

### 1. Field

The disclosure relates to an electronic device including a printed circuit board.

### 2. Description of Related Art

Advancing information communication technologies and semiconductor technologies accelerate the spread and use of various electronic devices. In particular, recent electronic devices are being developed to carry out communication while carried on.

The term “electronic device” may mean a device performing a particular function according to its equipped program, such as a home appliance, an electronic scheduler, a portable multimedia player, a mobile communication terminal, a tablet PC, a video/sound device, a desktop PC or laptop computer, a navigation for automobile, etc. For example, the electronic devices may output stored information as voices or images. As electronic devices are highly integrated, and high-speed or high-volume wireless communication becomes commonplace, an electronic device, such as a mobile communication terminal, is recently being equipped with a function. For example, an electronic device comes with the integrated functionality, including an entertainment function, such as playing video games, a multimedia function, such as replaying music/videos, a communication and security function for mobile banking, and a scheduling or e-wallet function. These electronic devices have been downsized to be conveniently carried by users.

The above-described information may be provided as related art for the purpose of helping understanding of the disclosure. No claim or determination is made as to whether any of the foregoing is applicable as background art in relation to the disclosure.

### SUMMARY

According to an aspect of the disclosure, an electronic device may include: a printed circuit board; and a capacitor on the printed circuit board. The printed circuit board may include: a conductive layer may include at least one slit in an area adjacent to the capacitor; and an insulation layer directly on the conductive layer and including a portion in the at least one slit. The at least one slit may be parallel to at least one side surface of the capacitor, and spaced apart from the at least one side surface of the capacitor by a first distance or less. The at least one slit may not overlap the capacitor when viewed from above.

The at least one slit may include one side having a second length extending parallel to the at least one side surface of the capacitor. The second length may be at least 1.4 times longer than a length of the at least one side surface of the capacitor.

The capacitor may be a multilayer ceramic capacitor (MLCC).

The at least one side surface of the capacitor may include: a first side surface facing a first direction, a second side surface facing a second direction opposite to the first direction, a third side surface facing a third direction perpendicular to the first direction and the second direction, and a fourth side surface facing a fourth direction opposite to the third direction.

The electronic device further may include at least one solder pad between the capacitor and the printed circuit board. The at least one solder pad may include a first solder pad coupled to a first direction side of a lower surface of the capacitor and a second solder pad coupled to a second direction side of the lower surface of the capacitor.

The at least one slit may be recessed downward from one surface of the conductive layer contacting the insulation layer.

A thickness of the at least one slit may be less than or equal to a thickness of the conductive layer.

The at least one slit may include: a first slit parallel to the first side of the capacitor, and a third slit perpendicular to the first slit and parallel to the third side surface of the capacitor.

The at least one slit may include: a first side of a second length parallel to an adjacent side of the at least one side surface of the capacitor, and a second side of a third length extending perpendicular to the first side. The second length may be at least twice a length of an adjacent side of the at least one side surface of the capacitor.

The at least one slit may include: a first slit adjacent to the first side surface and extending in the third direction, and a second slit adjacent to the second side surface and extending in the third direction.

The at least one slit further may include: a third slit adjacent to the third side surface, and extending in the first direction, and a fourth slit adjacent to the fourth side surface, and extending in the first direction.

The at least one slit may include a fifth slit facing a lower surface of the capacitor.

The first distance may be 0.2 mm or less.

The portion may protrude downward and fill the at least one slit.

The at least one slit may include: a first portion at the third side of the capacitor and parallel to the third side, a second portion at the fourth side of the capacitor and parallel to the fourth side, and a third portion connected to the first portion and the second portion and facing a lower surface of the capacitor.

According to an aspect of the disclosure, an electronic device, may include: a printed circuit board; and a capacitor on the printed circuit board. The printed circuit board may include: a first conductive layer may include a first slit layer in an area adjacent to the capacitor; a first insulation layer on the first conductive layer and including a first portion in the first slit layer; a second conductive layer on the first insulation layer and including a second slit layer in the area adjacent to the capacitor; and a second insulation layer on the second conductive layer and including a second portion in the second slit layer. A slit in the first slit layer and the second slit layer may be adjacent to at least one side surface of the capacitor and spaced apart from the at least one side surface of the capacitor by a first distance or less.

The capacitor may be a multi-layer ceramic capacitor (MLCC).

The slit may include at least one slit in the first slit layer and a slit in the second slit layer having a same shape as the at least one slit in the first slit layer.

The slit may include a slit in the first slit layer and a slit in the second slit layer having a shape different than the slit in the first slit layer.

The first slit layer and the second slit layer include at least one of: a first slit at a first side surface of the capacitor and adjacent to a first side surface, a second slit at a second side surface of the capacitor and adjacent to a second side surface, a third slit at a third side surface of the capacitor and adjacent to a third side surface, a fourth slit at a fourth side surface of the capacitor and adjacent to the fourth side surface, and a fifth slit facing a lower surface of the capacitor.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of an electronic device in a network environment according to one or more embodiments of the disclosure;

FIG. 2 is a front perspective view of an electronic device according to one or more embodiments of the disclosure;

FIG. 3 is a rear perspective view of the electronic device of FIG. 2 according to one or more embodiments of the disclosure;

FIG. 4A is a front exploded perspective view of the electronic device of FIG. 2 according to one or more embodiments of the disclosure;

FIG. 4B is a rear exploded perspective view of the electronic device of FIG. 2 according to one or more embodiments of the disclosure;

FIG. 5 is a cross-sectional view of the printed circuit board of FIG. 4A according to one or more embodiments of the disclosure, taken along line A-A′;

FIG. 6 is a view of a capacitor and a printed circuit board according to one or more embodiments of the disclosure, as viewed from above;

FIG. 7 is a view of a capacitor according to one or more embodiments of the disclosure, as viewed from above;

FIG. 8 is a view of a printed circuit board including a slit according to one or more embodiments of the disclosure, as viewed from above;

FIG. 9 is a view of a printed circuit board according to one or more embodiments of the disclosure, as viewed from above, and an enlarged view of a slit;

FIG. 10 is a graph of a noise reduction degree according to a first distance according to one or more embodiments of the disclosure;

FIG. 11 is a graph of a noise reduction degree according to a second length according to one or more embodiments of the disclosure;

FIG. 12 is a graph of a noise reduction degree according to a slit disposition according to one or more embodiments of the disclosure;

FIG. 13 is a view of a capacitor and a printed circuit board according to one or more embodiments of the disclosure, as viewed from above;

FIG. 14 is a view of a printed circuit board including a slit according to one or more embodiments of the disclosure, as viewed from above;

FIG. 15 is a view of a capacitor and a printed circuit board according to one or more embodiments of the disclosure, as viewed from a side surface thereof;

FIG. 16 is a view of a capacitor and a printed circuit board according to one or more embodiments of the disclosure, as viewed from a side surface thereof; and

FIG. 17 is a view of a capacitor and a printed circuit board according to one or more embodiments of the disclosure, as viewed from a side surface thereof.

### DETAILED DESCRIPTION

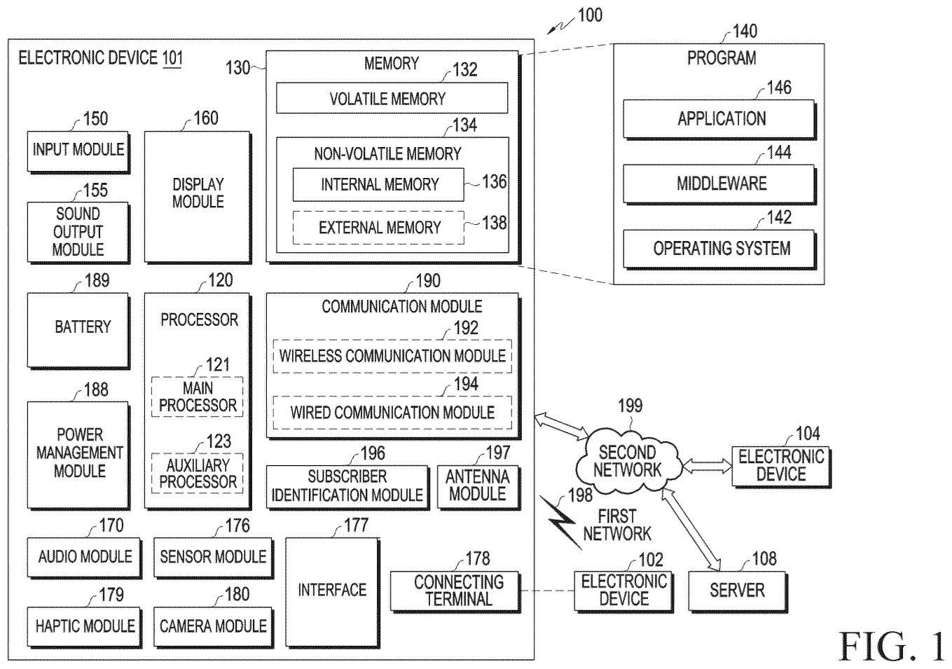

FIG. 1 is a block diagram illustrating an electronic device 101 in a network environment 100 according to various embodiments.

Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal According to an embodiment, the display module 160 may include a first display module 351 corresponding to the user's left eye and/or a second display module 353 corresponding to the user's right eye, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store a piece of data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support a requirement specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to an embodiment of the disclosure may be one type of electronic device. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

An embodiment of the disclosure and terms used therein are not intended to limit the technical features described in the disclosure to specific embodiments, and should be understood to include a modification, equivalent, or substitute of the embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or Further, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

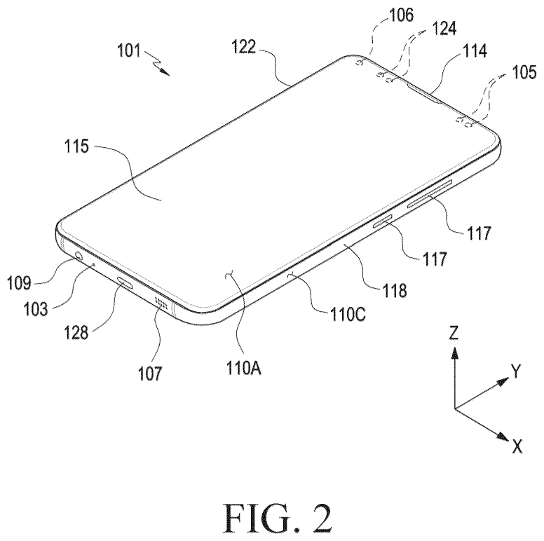

FIG. 2 is a front perspective view of an electronic device 101 according to one or more embodiments of the disclosure.

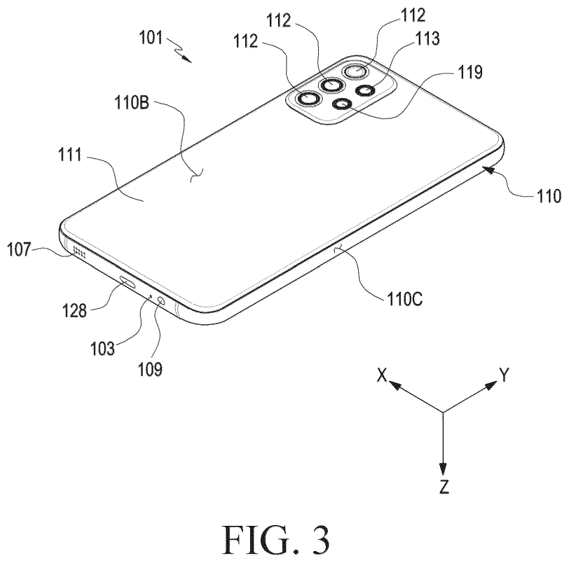

FIG. 3 is a rear perspective view of the electronic device 101 of FIG. 2 according to one or more embodiments of the disclosure.

Referring to FIGS. 2 and 3, according to one or more embodiments, an electronic device 101 (e.g., the electronic device 101 of FIG. 1) may include a housing 110 including a first surface (or front surface) 110A, a second surface (or rear surface) 110B, and a side surface 110C surrounding a space between the first surface 110A and the second surface 110B. According to one or more embodiments, the housing 110 may be a structure forming the first surface 110A of FIG. 2, the second surface 110B of FIG. 3, and some of the side surfaces 110C.

According to one or more embodiments, at least part of the first surface 110A may have a substantially transparent front plate 122 (e.g., a glass plate or polymer plate including various coat layers). The second surface 110B may be formed of a substantially opaque rear plate 111. The rear plate 111 may be formed of, e.g., laminated or colored glass, ceramic, polymer, metal (e.g., aluminum, stainless steel (STS), or magnesium), or a combination of at least two thereof. The side surface 110C may be formed by a side structure (or a “side bezel structure”) 118 that couples to the front plate 122 and the rear plate 111 and includes a metal and/or polymer. In one or more embodiments, the rear plate 111 and the side structure 118 may be integrally formed together and include the same material (e.g., a metal, such as aluminum).

According to one or more embodiments, the front plate 122 may include area(s) that bend from at least a portion of an edge toward the rear plate 111 and seamlessly extend. For example, only one of the areas of the front plate 122 (or the rear plate 111), which bend to the rear plate 111 (or front plate 122) and extend may be included in one edge of the first surface 110A. According to one or more embodiments, the front plate 122 or rear plate 111 may be substantially flat and, in this case, may not include an area bending and extending. When an area bending and extending is included in the front plate 122 or rear plate 111, the thickness of the electronic device 101 at the portion including the area bending and extending may be smaller than the thickness of the rest.

According to one or more embodiments, the electronic device 101 may include at least one of a display 115, an audio module (e.g., the microphone hole 103, the external speaker hole 107, and the phone receiver hole 114), a sensor module (e.g., the first sensor module 124, the second sensor module, or the third sensor module 119), a camera module (e.g., the first camera device 105, the second camera device 112, or the flash 113), a key input device 117, a light emitting device 106, and a connector hole (e.g., the first connector hole 128 or the second connector hole 109). In one or more embodiments, the electronic device 101 may exclude at least one (e.g., the key input device 117 or the light emitting device 106) of the components or may add other components.

The display 115 may output a screen or be visually exposed through a significant portion of the first surface 110A (e.g., the front plate 122), for example. In one or more embodiments, at least a portion of the display 115 may be visually exposed through the front plate 122 forming the first surface 110A, or through a portion of the side surface 110C. In one or more embodiments, the edge of the display 115 may be formed to be substantially the same in shape as an adjacent outer edge of the front plate 122. In one or more embodiments, the interval between the outer edge of the display 115 and the outer edge of the front plate 122 may remain substantially even to give a larger area of visual exposure of the display 115.

According to one or more embodiments, a recess or an opening may be formed in a portion of the screen display area of the display 115, and there may be included at least one of an audio module (e.g., the phone receiver hole 114), a sensor module (e.g., the first sensor module 124), a camera module (e.g., the first camera device 105), and a light emitting device 106 that are aligned with the recess or the opening. In one or more embodiments, at least one of the audio module (e.g., the phone receiver hole 114), sensor module (e.g., the first sensor module 124), camera module (e.g., the first camera device 105), fingerprint sensor, and light emitting device 106 may be included on the rear surface of the screen display area of the display 115. In one or more embodiments, the display 115 may be disposed to be coupled with, or adjacent, a touch detecting circuit, a pressure sensor capable of measuring the strength (pressure) of touches, and/or a digitizer for detecting a magnetic field-type stylus pen.

According to one or more embodiments, the audio modules 103, 107, and 114 may include a microphone hole 103 and speaker holes (e.g., the external speaker hole 107 and the phone receiver hole 114). A microphone for acquiring external sounds may be disposed in the microphone hole 103. In one or more embodiments, a plurality of microphones may be disposed to detect the direction of the sound. The speaker holes may include an external speaker hole 107 and a phone receiver hole 114. According to one or more embodiments, the speaker holes (e.g., the external speaker hole 107 and the phone receiver hole 114) and the microphone hole 103 may be implemented as a single hole, or speakers may be included without the speaker holes (e.g., the external speaker hole 107 and the phone receiver hole 114) (e.g., piezo speakers).

According to one or more embodiments, the sensor module may generate an electrical signal or data value corresponding to an internal operating state or external environmental state of the electronic device 101. The sensor modules may include a first sensor module 124 (e.g., a proximity sensor) and/or a second sensor module (e.g., a fingerprint sensor) disposed on the first surface 110A of the housing 110 and/or a third sensor module 119 disposed on the second surface 110B of the housing 110. The second sensor module (e.g., a fingerprint sensor) may be disposed on the second surface 110B or side surface 110C as well as the first surface 110A (e.g., the display 115) of the housing 110. The electronic device 101 may further include, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 124.

According to one or more embodiments, the camera modules may include a first camera device 105 disposed on the first surface 110A of the electronic device 101, and a second camera device 112 and/or a flash 113 disposed on the second surface 110B. The camera devices (e.g., the first camera device 105 and the second camera device 112) may include one or more lenses, an image sensor, and/or an image signal processor. The flash 113 may include, e.g., a light emitting diode (LED) or a xenon lamp. In one or more embodiments, one or more lenses (an infrared (IR) camera, a wide-angle lens, and a telephoto lens) and image sensors may be disposed on one surface of the electronic device 101. In one or more embodiments, flash 113 may emit infrared light. The infrared light emitted by the flash 113 and reflected by the subject may be received through the third sensor module 119. The electronic device 101 or the processor (e.g., the processor 120 of FIG. 1) of the electronic device 101 may detect depth information about the subject based on the time point when the infrared light is received from the third sensor module 119.

According to one or more embodiments, the key input device 117 may be disposed on the side surface 110C of the housing 110. In one or more embodiments, the electronic device 101 may exclude all or some of the above-mentioned key input devices 117 and the excluded key input devices 117 may be implemented in other forms, e.g., as soft keys, on the display 115. In one or more embodiments, the key input device may include the sensor module disposed on the second surface 110B of the housing 110.

According to one or more embodiments, the light emitting device 106 may be disposed on the first surface 110A of the housing 110, for example. The light emitting device 106 may provide, e.g., information about the state of the electronic device 101 in the form of light. In one or more embodiments, the light emitting device 106 may provide a light source that interacts with, e.g., the camera module (e.g., the first camera device 105). The light emitting device 106 may include, e.g., a light emitting diode (LED), an infrared (IR) LED, or a xenon lamp.

According to one or more embodiments, the connector holes (e.g., the first connector hole 128 or the second connector hole 109) may include, e.g., a first connector hole 128 for receiving a connector (e.g., a USB connector) for transmitting/receiving power and/or data to/from an external electronic device (e.g., the electronic device 1002 of FIG. 1) and/or a second connector hole 109 (e.g., an earphone jack) for receiving a connector for transmitting/receiving audio signals to/from the external electronic device.

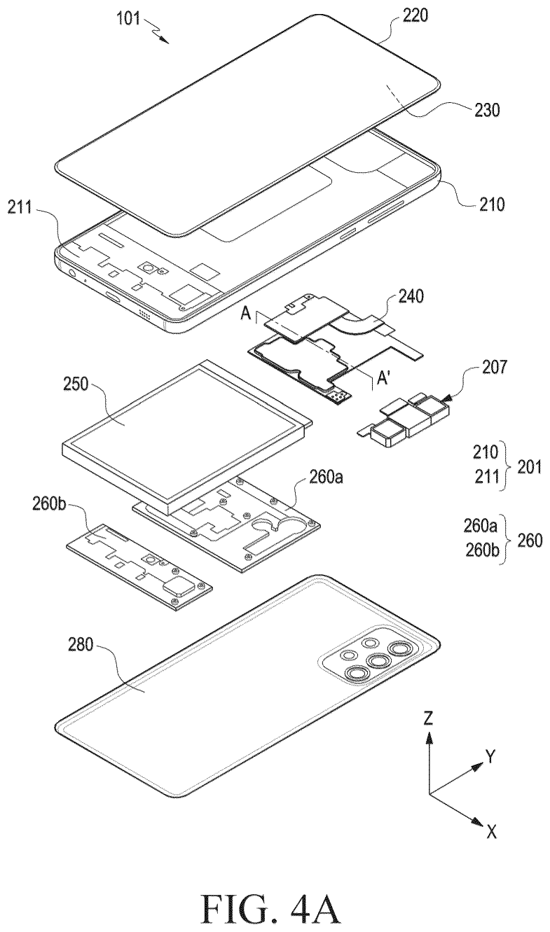

FIG. 4A is a front exploded perspective view of the electronic device 101 of FIG. 2 according to one or more embodiments of the disclosure.

FIG. 4B is a rear exploded perspective view of the electronic device 101 of FIG. 2 according to one or more embodiments of the disclosure.

Referring to FIGS. 4A and 4B, an electronic device 101 (e.g., the electronic device 101 of FIG. 1, 2, or 3) may include a side structure 210, a first supporting member 211 (e.g., a bracket), a front plate 220 (e.g., the front plate 122 of FIG. 2), a display 230 (e.g., the display 115 of FIGS. 2 and 3), a printed circuit board (or a board assembly) 240, a battery 250, a second supporting member 260 (e.g., a rear case), an antenna, a camera assembly 207, and a rear plate 280 (e.g., the rear plate 111 of FIG. 3).

According to one or more embodiments, the electronic device 101 may exclude at least one (e.g., the first supporting member 211 or the second supporting member 260) of the components or may add other components. At least one of the components of the electronic device 101 may be the same or similar to at least one of the components of the electronic device 101 of FIG. 2 or 3 and no duplicate description is made below.

According to one or more embodiments, the first supporting member 211 may be disposed inside the electronic device 101 to be connected with the side structure 210 or integrated with the side structure 210. The first supporting member 211 may be formed of, e.g., a metallic material and/or non-metallic material (e.g., polymer). When at least partially formed of a metallic material, a portion of the side structure 210 or the first supporting member 211 may function as an antenna. The display 230 may be joined onto one surface of the first supporting member 211, and the printed circuit board 240 may be joined onto the opposite surface of the first supporting member 232. A processor (e.g., the processor 120 of FIG. 1), memory (e.g., the memory 130 of FIG. 1), and/or an interface (e.g., the interface 177 of FIG. 1) may be mounted on the printed circuit board 240. The processor may include one or more of, e.g., a central processing unit, an application processor, a graphic processing device, an image signal processing, a sensor hub processor, or a communication processor.

According to one or more embodiments, the first supporting member 211 and the side structure 210 may be collectively referred to as a front case or a housing 201. According to one or more embodiments, the housing 201 may be generally understood as a structure for receiving, protecting, or disposing the printed circuit board 240 or the battery 250. In one or more embodiments, the housing 201 may be understood as including a structure that the user may visually or tactfully recognize from the exterior of the electronic device 101, e.g., the side structure 210, the front plate 220, and/or the rear plate 280. In one or more embodiments, the ‘front or rear surface of the housing 201’ may mean the first surface 110A of FIG. 2 or the second surface 110B of FIG. 3. In one or more embodiments, the first supporting member 211 may be disposed between the front plate 220 (e.g., the first surface 110A of FIG. 2) and the rear plate 280 (e.g., the second surface 110B of FIG. 3) and may function as a structure for placing an electrical/electronic component, such as the printed circuit board 240 or the camera assembly 207.

According to one or more embodiments, the display 230 may include a display panel 231 and a flexible printed circuit board 233 extending from the display panel 231. It may be understood that the flexible printed circuit board 233 is, e.g., electrically connected to the display panel 231 while at least partially disposed on the rear surface of the display panel 231. In one or more embodiments, reference number ‘231’ may be understood as a protective sheet disposed on the rear surface of the display panel. For example, the protective sheet may be understood as a portion of the display panel 231 unless otherwise designated in the detailed description below. In one or more embodiments, the protective sheet may function as a cushioning structure that absorbs external force (e.g., a low-density elastic material, such as a sponge) or an electromagnetic shielding structure (e.g., a copper sheet (CU sheet)). According to one or more embodiments, the display 230 may be disposed on the inner surface of the front plate 220 and, by including a light emitting layer, output a screen through at least a portion of the front plate 220 or the first surface 110A of FIG. 2. As mentioned above, the display 230 may output substantially the entire area of the front plate 220 or the first surface 110A of FIG. 2.

According to one or more embodiments, the memory may include, e.g., a volatile or non-volatile memory.

According to one or more embodiments, the interface may include a high definition multimedia interface (HDMI), a universal serial bus (USB) interface, a secure digital (SD) card interface, and/or an audio interface. The interface may electrically or physically connect, e.g., the electronic device 101 with an external electronic device and may include a USB connector, an SD card/multimedia card (MMC) connector, or an audio connector.

According to one or more embodiments, the second supporting member 260 may include an upper supporting member 260a and a lower supporting member 260b. In one or more embodiments, the upper supporting member 260a, together with a portion of the first supporting member 211, may be disposed to surround the printed circuit board 240. A circuit device (e.g., a processor, a communication module, or memory) implemented in the form of an integrated circuit chip or various electrical/electronic components may be disposed on the printed circuit board 240. According to one or more embodiments, the printed circuit board 240 may receive an electromagnetic shielding environment from the upper supporting member 260a. In one or more embodiments, the lower supporting member 260b may be utilized as a structure in which electrical/electronic components, such as a speaker module and an interface (e.g., a USB connector, an SD card/MMC connector, or an audio connector) may be disposed. In one or more embodiments, electrical/electronic components, such as a speaker module and an interface (e.g., a USB connector, an SD card/MMC connector, or an audio connector) may be disposed on an additional printed circuit board. In this case, the lower supporting member 260b, together with the other part of the first supporting member 211, may be disposed to surround the additional printed circuit board. A speaker module or interface disposed on an additional printed circuit board or lower supporting member 260b may be disposed corresponding to the connector hole (e.g., the first connector hole 128 or the second connector hole 109) or the audio module (e.g., the microphone hole 103 or the speaker hole (e.g., the external speaker hole 107 or the phone receiver hole 114)) of FIG. 2.

According to one or more embodiments, the battery 250 may be a device for supplying power to at least one component of the electronic device 101. The battery 189 may include, e.g., a primary cell which is not rechargeable, a secondary cell which is rechargeable, or a fuel cell. At least a portion of the battery 250 may be disposed on substantially the same plane as the printed circuit board 240. For example, the battery 250 may be integrally or detachably disposed inside the electronic device 101.

The antenna may include a conductor pattern implemented on the surface of the second supporting member 260 through, e.g., laser direct structuring. In one or more embodiments, the antenna may include a printed circuit pattern formed on the surface of the thin film. The thin film-type antenna may be disposed between the rear plate 280 and the battery 250. The antenna may include, e.g., a near-field communication (NFC) antenna, a wireless charging antenna, and/or a magnetic secure transmission (MST) antenna. The antenna may perform short-range communication with, e.g., an external device or may wirelessly transmit or receive power necessary for charging. In one or more embodiments of the disclosure, another antenna structure may be formed by a portion or combination of the side structure 210 and/or the first supporting member 211.

According to one or more embodiments, the camera assembly 207 may include at least one camera module. Inside the electronic device 101, the camera assembly 207 may receive at least a portion of the light incident through the optical hole or the camera windows 212, 213, and 219. In one or more embodiments, the camera assembly 207 may be disposed on the first supporting member 211 in a position adjacent to the printed circuit board 240. In one or more embodiments, the camera module(s) of the camera assembly 207 may be generally aligned with either one of the camera windows 212, 213, and 219 and be a least partially surrounded by the second supporting member 260 (e.g., the upper supporting member 260a).

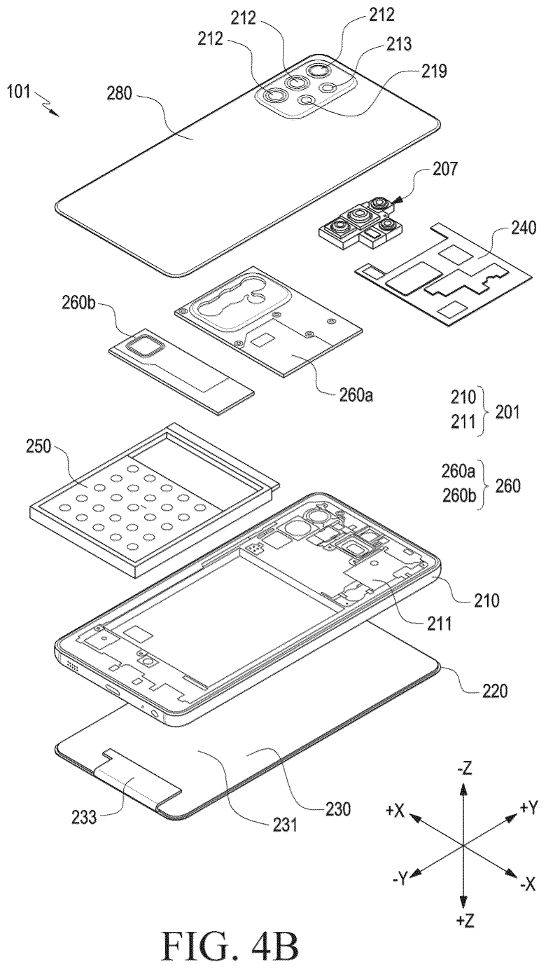

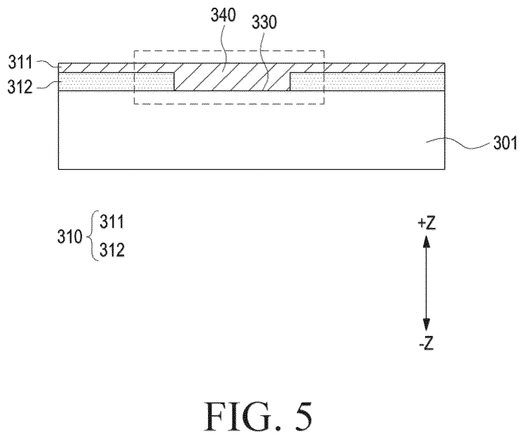

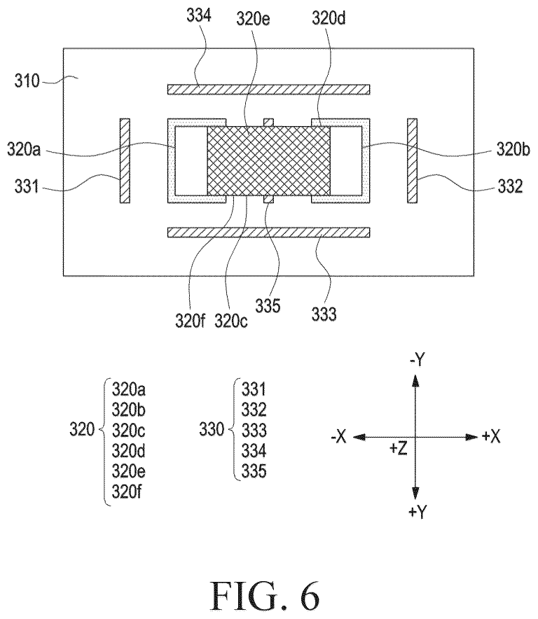

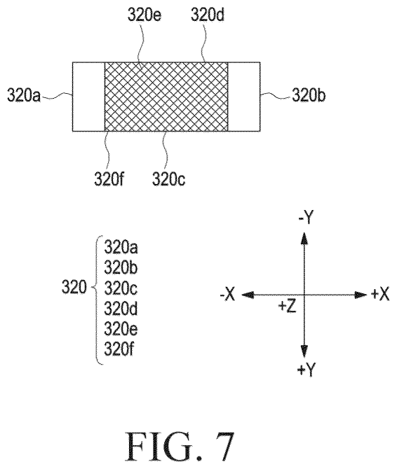

FIG. 5 is a cross-sectional view of the printed circuit board of FIG. 4A (e.g., the printed circuit board 240 of FIG. 4A) according to one or more embodiments of the disclosure, taken along line A-A′. FIG. 6 is a view of a capacitor and a printed circuit board according to one or more embodiments of the disclosure, as viewed from above. FIG. 7 is a view of a capacitor according to one or more embodiments of the disclosure, as viewed from above. FIG. 8 is a view of a printed circuit board including a slit according to one or more embodiments of the disclosure, as viewed from above.

Referring to FIGS. 5 to 8, an electronic device may include a printed circuit board 310 and a capacitor 320 disposed on the printed circuit board 310. The configuration of the printed circuit board 310 of FIGS. 5 to 8 may be identical in whole or part to the configuration of the printed circuit board 240 of FIGS. 2 to 4B. The structure of FIGS. 5 to 8 may be selectively combinable with the structures of FIGS. 2 to 4B.

According to one or more embodiments, the capacitor 320 may refer to a device that stores electrical capacity as electrical potential energy on a circuit board. For example, the capacitor 320 may be any one of a thin film capacitor, a ceramic capacitor, a silicon capacitor, or an aluminum electrolytic capacitor. For example, the capacitor 320 may be a multi-layer ceramic capacitor (MLCC) 320. The multi-layer ceramic capacitor 320 may be a component that controls current to flow constantly through the circuit board of the electronic device. The multi-layer ceramic capacitor 320 (MLCC), which is one of the stacked chip electronic components, may be used in various electronic devices due to its small size, high capacity, and easy mounting. The multi-layer ceramic capacitor 320 may be mounted on a printed circuit board of various electronic products, such as displays, such as a liquid crystal display (LCD) and a plasma display panel (PDP), a computer, a personal digital assistant (PDA), and a mobile phone, and may be used in a chip-type capacitor for charging or discharging electricity.

According to one or more embodiments, the multi-layer ceramic capacitor 320 may have a structure in which internal electrodes of different polarities are alternately disposed between a plurality of dielectric layers. In this case, since the dielectric layer has piezoelectricity, when a direct current or an alternating current voltage is applied to the multi-layer ceramic capacitor 320, a piezoelectric phenomenon may occur between the internal electrodes, and the volume of the ceramic main body may be expanded and contracted according to the frequency, thereby generating periodic vibration. The vibration may be transferred to the printed circuit board 310 through an external electrode of the multi-layer ceramic capacitor 320 and a solder connecting the external electrode and the printed circuit board 310 to generate a vibration sound that becomes noise as the entire printed circuit board 310 becomes an acoustic reflective surface. Such a vibration sound may correspond to an audible frequency in the range of about 20 Hz to 20.00 Hz that causes discomfort to a person, and such a vibration sound that causes discomfort to a person is called acoustic noise. In one or more embodiments of the disclosure, the printed circuit board 310 having a stacked structure including the slit 330 allows the vibration energy of the capacitor 320 to be attenuated while passing through the printed circuit board 310 having heterogeneous media having different densities, thereby reducing noise in an audible frequency band. Hereinafter, the structure of the printed circuit board 310 and the relationship with the capacitor 320 are described in detail.

According to one or more embodiments, the capacitor 320 may be disposed on the printed circuit board 310. According to one or more embodiments, the capacitor 320 may have, e.g., a rectangular shape. For example, the capacitor 320 may include a first side surface 320a facing in a left direction (−X direction, first direction), a second side surface 320b facing in a right direction (+X direction, second direction), a third side surface 320c facing in a front direction (+Y direction, third direction), and a fourth side surface 320d facing in a rear direction (−Y direction, fourth direction). As shown in FIG. 7, the capacitor 320 may include an upper surface 320e disposed perpendicular to a plurality of side surfaces (e.g., the first side surface 320a, the second side surface 320b, the third side surface 320c, or the fourth side surface 320d) and facing in an upper direction (+Z direction) and a lower surface 320f facing in a lower direction (−Z direction). The lower surface 320f of the capacitor 320 may face the printed circuit board 310. However, the shape of the capacitor 320 is not limited to the above embodiment, and various changes may be made to the design.

According to one or more embodiments, the electronic device may include at least one solder pad 321 and 322 disposed between the capacitor 320 and the printed circuit board 310. The solder pads 321 and 322 may be attached to the lower surface 320f of the capacitor 320, and may allow the capacitor 320 to be fixed and electrically connected to the printed circuit board 310. For example, the at least one solder pad 321 and 322 may include a first solder pad 321 attached to the lower surface 320f of the capacitor 320 in the left direction (−X direction, the first direction) and a second solder pad 322 attached to the lower surface 320f of the capacitor 320 in the right direction (+X direction, the second direction).

According to one or more embodiments, the first solder pad 321 may have a rectangular shape. However, the shape of the solder pad 321 is not limited to the above embodiment, and various changes may be made to the design. According to one or more embodiments, the second solder pad 322 may have, e.g., a rectangular shape. However, the shape of the second solder pad 322 is not limited to the above embodiment, and various changes may be made to the design.

According to one or more embodiments, the printed circuit board 310 may include an insulation layer 311 and a conductive layer 312.

According to one or more embodiments, the conductive layer 312 may be formed of a copper foil, and a circuit pattern may be formed on at least a portion thereof. For example, the conductive layer 312 may be formed by casting, laminating, or sputtering.

According to one or more embodiments, the conductive layer 312 may include at least one slit 330 formed in an area adjacent to the capacitor 320. For example, the slit 330 may be formed to be recessed downward (−Z direction) from one surface of the conductive layer 312. For example, the thickness (length in the Z-axis direction) of the slit 330 may be thinner than or equal to the thickness of the conductive layer 312. For example, when the thickness of the slit 330 is equal to the thickness of the conductive layer 312, a portion of the conductive layer 312 may be removed or penetrated to form the slit 330. According to one or more embodiments, the conductive layer 312 may be a conductive layer disposed in the uppermost direction (+Z direction) among a plurality of conductive layers.

According to one or more embodiments, the insulation layer 311 may be disposed on the conductive layer 312. For example, the insulation layer 311 may include a prepreg. For example, the insulation layer 311 may include resin, filler, and glass fabric. According to one or more embodiments, the insulation layer 311 may include a portion 340 disposed in the at least one slit 330. For example, the portion 340 may be formed to protrude in the lower direction (−Z direction) in which the conductive layer 312 is disposed. According to one or more embodiments, the insulation layer 311 may be an insulation layer disposed in the uppermost direction (+Z direction) among a plurality of insulation layers.

According to one or more embodiments, referring to FIG. 5, the printed circuit board 310 may include lower layers 301 disposed in the lower direction (−Z direction) of the conductive layer 312 (e.g., a portion encompassing the remaining layers disposed in the lower direction (−Z direction) of the printed circuit board such as conductive layers and insulation layers).

According to one or more embodiments, the at least one slit 330 may be disposed adjacent to the at least one side surface 320a, 320b, 320c, and 320d of the capacitor 320. For example, the at least one slit 330 may be disposed parallel to the at least one side surface 320a, 320b, 320c, and 320d of the capacitor 320. For example, the at least one slit 330 may be disposed adjacent to and/or parallel to the first side surface 320a of the capacitor 320. For example, the at least one slit 330 may be disposed adjacent to and/or parallel to the second side surface 320b of the capacitor 320. According to one or more embodiments, the at least one slit 330 may include a first slit 331 disposed in the left direction (−X direction, the first direction) of the capacitor 320 and disposed adjacent to and/or parallel to the first side surface 320a, a second slit 332 disposed in the right direction (+X direction, the second direction) of the capacitor 320 and disposed adjacent to and/or parallel to the second side surface 320b, a third slit 333 disposed in the front direction (+Y direction, the third direction) of the capacitor 320 and disposed adjacent to and/or parallel to the third side surface 320c, and a fourth slit 334 disposed in the rear direction (−Y direction, the fourth direction) of the capacitor 320 and disposed adjacent to and/or parallel to the fourth side surface 320d.

According to one or more embodiments, the at least one slit 330 may be disposed under the lower surface 320f of the capacitor 320. For example, the at least one slit 330 may further include a fifth slit 330 disposed to face the lower surface 320f of the capacitor 320.

According to one or more embodiments, the at least one slit 330 may be disposed parallel to at least one edge of the at least one solder pad 321. For example, the first slit 331 may be disposed adjacent to the left direction (−X direction, the first direction) of the first solder pad 321. For example, the second slit 332 may be disposed adjacent to the right direction (+X direction, the second direction) of the second solder pad 322. For example, the third slit 333 may be disposed adjacent to the front direction (+Y direction, the third direction) of the first solder pad 321 and/or the second solder pad 322. For example, the fourth slit 334 may be disposed adjacent to the rear direction (−Y direction, the fourth direction) of the first solder pad 321 and/or the second solder pad 322. For example, the fifth slit 335 may be disposed in the right direction (+X direction, second direction) of the first solder pad 321 and the left direction (−X direction, first direction) of the second solder pad 322. For example, the fifth slit 335 may be disposed between the first solder pad 321 and the second solder pad 322.

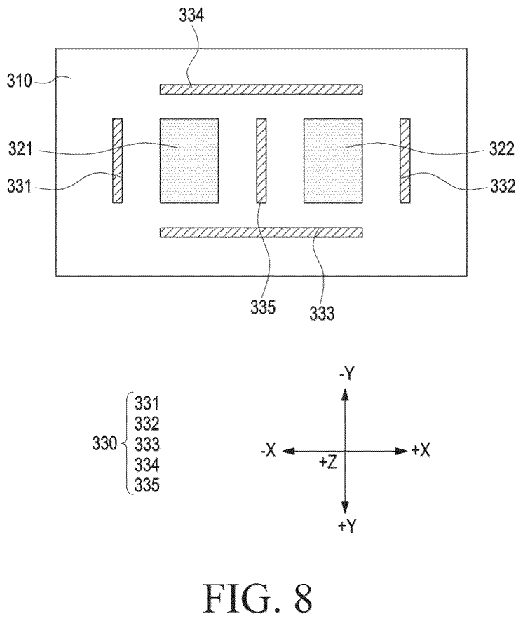

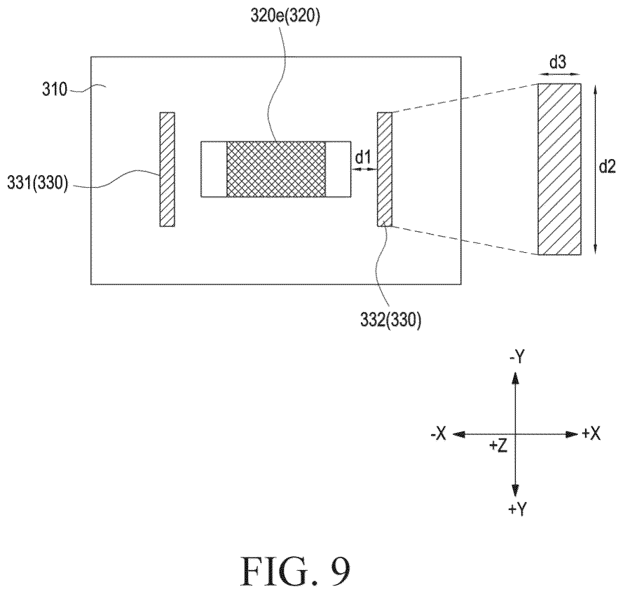

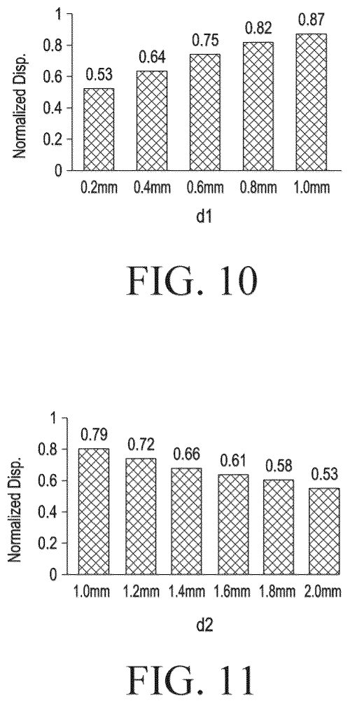

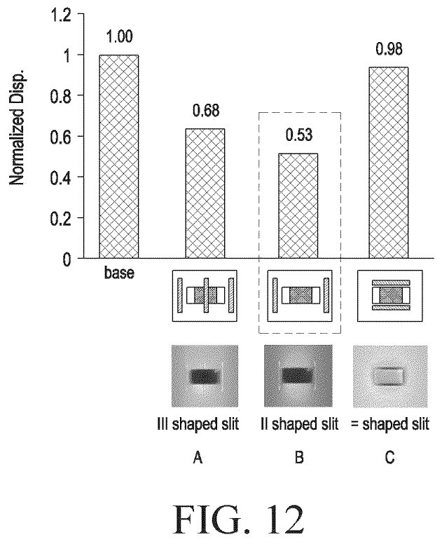

FIG. 9 is a view of a printed circuit board according to one or more embodiments of the disclosure, as viewed from above, and an enlarged view of a slit. FIG. 10 is a graph of a noise reduction degree according to a first distance according to one or more embodiments of the disclosure. FIG. 11 is a graph of a noise reduction degree according to a second length according to one or more embodiments of the disclosure. FIG. 12 is a graph of a noise reduction degree according to a slit disposition according to one or more embodiments of the disclosure.

Referring to FIGS. 9 to 12, an electronic device may include a printed circuit board 310 and a capacitor 320 disposed on the printed circuit board 310. The configuration of the printed circuit board 310 and the capacitor 320 of FIGS. 9 to 12 may be identical in whole or part to the configuration of the printed circuit board 310 and the capacitor 320 of FIGS. 5 to 8. The structure of FIGS. 9 to 12 may be selectively combinable with the structures of FIGS. 5 to 8.

According to one or more embodiments, the at least one slit 330 may be spaced apart from the at least one side surface of the capacitor 320 and/or the at least one solder pad 321 by a first distance d1 or less. For example, the first slit 331 may be spaced apart from the first side surface 320a of the capacitor 320 by the first distance d1 or less. For example, the second slit 332 may be spaced apart from the second side surface 320b of the capacitor 320 by the first distance d1 or less. For example, the third slit 333 may be spaced apart from the third side surface 320c of the capacitor 320 by the first distance d1 or less. For example, the fourth slit 334 may be spaced apart from the fourth side surface 320d of the capacitor 320 by the first distance d1 or less.

FIG. 10 is a graph of a noise reduction degree according to a first distance according to one or more embodiments of the disclosure. According to one or more embodiments, referring to FIG. 10, as the first distance d1 decreases, the noise reduction rate may increase. For example, the first distance d1 may be about 0.05 mm or more and about 0.2 mm or less. For example, when the first distance d1 is 1.0 mm, noise may be 0.87. For example, when the first distance d1 is 0.8 mm, noise may be 0.82. For example, when the first distance d1 is 0.6 mm, noise may be 0.75. For example, when the first distance d1 is 0.4 mm, noise may be 0.64. For example, when the first distance d1 is 0.2 mm, noise may be 0.53.

According to one or more embodiments, the first distance d1 may be 1.0 mm or less. For example, the first distance d1 may be 0.2 mm or less. For example, the first distance d1 may be 0.1 mm or more and 0.2 mm or less.

According to one or more embodiments, the third length d3, which is the length of the edge perpendicular to the side surface of the capacitor 320 adjacent to the slit 330, may be shorter than the second length d2. The noise reduction rate may increase as the third length d3 increases, but it may be mounted considering the mounting space of the printed circuit board 310. The third length d3 may be equal to or longer than, e.g., about 0.1 mm.

FIG. 11 is a graph of a noise reduction degree according to a second length according to one or more embodiments of the disclosure. According to one or more embodiments, referring to FIG. 11, as the second length d2 which is the length of the edge parallel to the side surface of the capacitor 320 adjacent to the slit 330 increases, the noise reduction rate may increase. For example, when the vertical length (Y-axis length) of the capacitor 320 is 1.0 mm and the second length d2 is 1.0 mm, the noise may be 0.79. For example, when the second length d2 is 1.2 mm, the noise may be 0.72. For example, when the second length d2 is 1.4 mm, the noise may be 0.66. For example, when the second length d2 is 1.6 mm, the noise may be 0.61. For example, when the second length d2 is 1.8 mm, the noise may be 0.58. For example, when the second length d2 is 2.0 mm, the noise may be 0.53.

According to one or more embodiments, the second length d2, which is the length of the edge parallel to the side surface of the capacitor 320 of the slit 330, may be longer than the length of the capacitor 320. For example, when the vertical length (Y-axis length) of the capacitor 320 is 1.0 mm, the second length d2 may be 1.0 mm or more. For example, when the vertical length (Y-axis length) of the capacitor 320 is 1.0 mm, the second length d2 may be equal to or greater than 2.0 mm. For example, the second length d2 may be 1.0 mm or more and 2.0 mm or less.

FIG. 12 is a graph of a noise reduction degree according to a slit disposition according to one or more embodiments of the disclosure. According to one or more embodiments, comparison and review may be performed between the noise A when the slit 330 is disposed to correspond to the lower surface 320f of the capacitor 320, the noise B when the slit 330 is disposed adjacent to and/or parallel to the left direction and/or right direction of the capacitor 320, and the noise C when the slit 330 is disposed adjacent to and/or parallel to the front direction and/or rear direction of the capacitor 320.

For example, in the case of the general printed circuit board 310, when the noise is 1.0, and when the slit (e.g., the fifth slit 335) is disposed to correspond to the lower surface 320f of the capacitor 320 (A), the noise may be 0.68. When the slit (e.g., the first slit 331 or the second slit 332) is disposed adjacent to and/or parallel to the left direction and/or the right direction of the capacitor 320 (B), the noise may be 0.53. When the slit (e.g., the third slit 331 or the fourth slit 332) is disposed adjacent to and/or parallel to the front direction and/or the rear direction of the capacitor 320 (C), the noise may be 0.98. As a result of the experiment, it may be identified that noise is reduced when the slit 330 is disposed adjacent to the capacitor 320. As a result of the experiment, it may be identified that the noise reduction rate when the slit 330 is disposed adjacent to and/or parallel to the left direction and/or the right direction of the capacitor 320 is the largest. The portion where the solder pads 321 and 322 of the capacitor 320 are disposed may be an edge portion of the capacitor 320 and be an area in which the vibration of the capacitor 320 is concentrated. As the capacitor 320 contracts and/or expands, the printed circuit board may be bent upward or downward, and the vibration of the printed circuit board may be concentrated on the outer portions of the solder pads 321 and 322. Accordingly, when the slit (e.g., the first slit 331 or the second slit 332) is disposed adjacent to and/or parallel to the left direction and/or the right direction of the capacitor 320, which is the portion where vibration of the printed circuit board is concentrated (B), noise generation may be relatively significantly reduced.

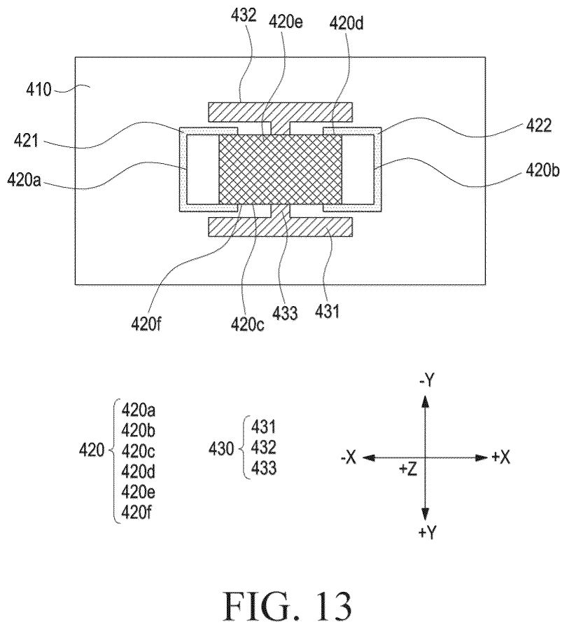

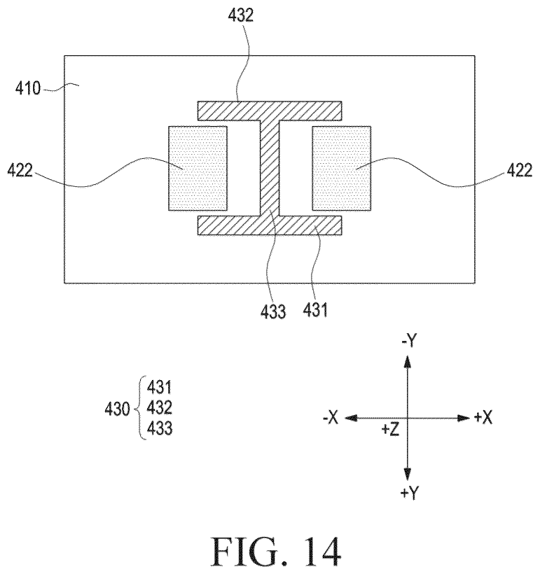

FIG. 13 is a view of a capacitor and a printed circuit board according to one or more embodiments of the disclosure, as viewed from above. FIG. 14 is a view of a printed circuit board including a slit according to one or more embodiments of the disclosure, as viewed from above.

Referring to FIGS. 13 and 14, an electronic device may include a printed circuit board 410, a capacitor 420 disposed on the printed circuit board 410, and a slit 430. The configurations of the printed circuit board 410, the capacitor 420, the solder pads 421 and 422, and the slit 430 of FIGS. 13 to 14 may be identical in whole or part to the configuration of the printed circuit board 310, the capacitor 320, the solder pads 321 and 322, and the slit 330 of FIGS. 5 to 12. The structure of FIGS. 13 and 14 may be selectively combinable with the structures of FIGS. 5 to 12.

According to one or more embodiments, at least a portion of the slit 430 may be disposed parallel to at least one side surface 420a, 420b, 420c, and 420d of the capacitor 420. For example, at least a portion of the slit 430 may be disposed parallel to the first side surface 420a of the capacitor 420. For example, at least a portion of the slit 430 may be disposed parallel to the fourth side surface 420d of the capacitor 420.

As shown in FIG. 13 according to one or more embodiments, the slit 430 may include a first portion 431 disposed in the front direction (+Y direction, third direction) of the capacitor 420 and disposed substantially parallel to the third side surface 420c, a second portion 432 disposed in the rear direction (−Y direction, fourth direction) of the capacitor 420 and disposed substantially parallel to the fourth side surface 420d, and a third portion 433 connected substantially perpendicularly to the first portion 431 and the second portion 432 and disposed between the first solder pad 421 and the second solder pad 422. For example, the slit may be the uppercase letter ‘I’. According to one or more embodiments, the third portion 433 may be disposed under the lower surface 420f of the capacitor 420. For example, the third portion 433 may be disposed to face the lower surface 420f of the capacitor 420.

According to one or more embodiments, at least a portion of the slit 430 may be disposed substantially parallel to at least one edge of the at least one solder pad 421 or 422. For example, the first portion 431 may be disposed adjacent to the front direction (+Y direction, fourth direction) of the first solder pad 421 and/or the second solder pad 422. For example, the second portion 432 may be disposed adjacent to the rear direction (−Y direction, fourth direction) of the first solder pad 421 and/or the second solder pad 422. For example, the third portion 433 may be disposed between the first solder pad 421 and the second solder pad 422.

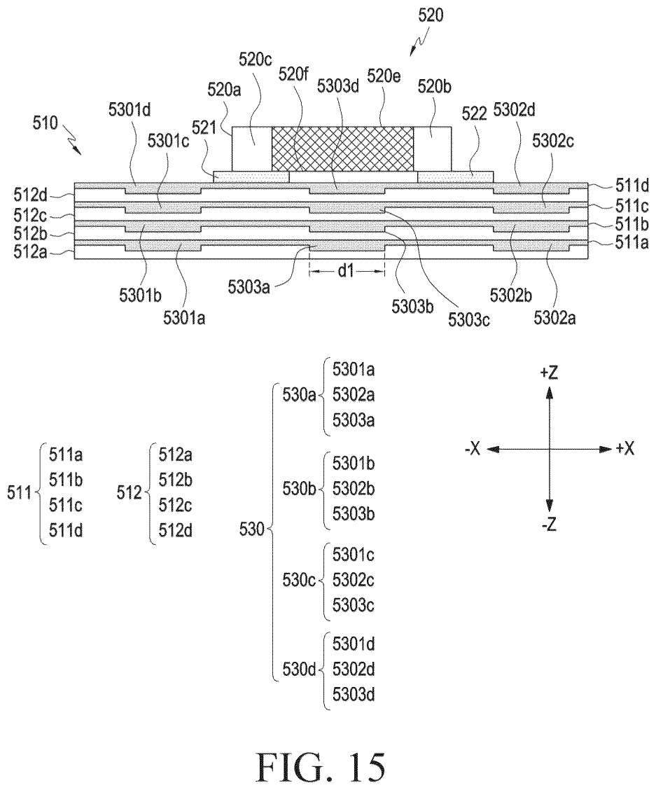

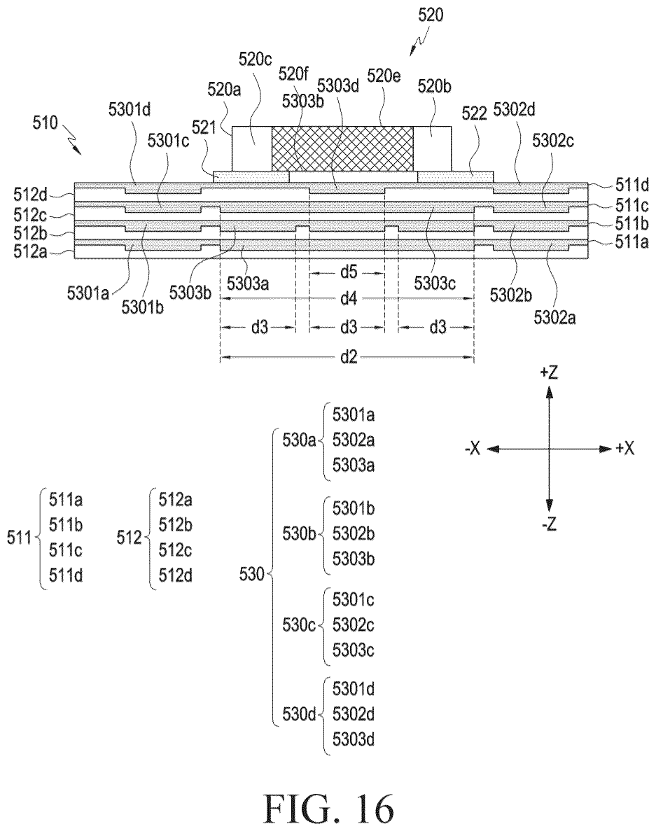

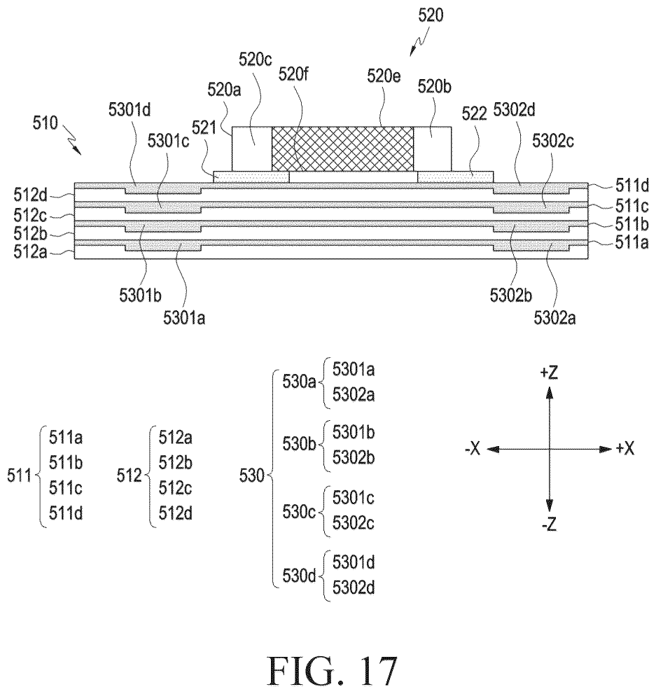

FIG. 15 is a view of a capacitor and a printed circuit board according to one or more embodiments of the disclosure, as viewed from a side surface thereof. FIG. 16 is a view of a capacitor and a printed circuit board according to one or more embodiments of the disclosure, as viewed from a side surface thereof. FIG. 17 is a view of a capacitor and a printed circuit board according to one or more embodiments of the disclosure, as viewed from a side surface thereof.

Referring to FIGS. 15 and 17, an electronic device may include a printed circuit board 510, a capacitor 520 disposed on the printed circuit board 510, and a slit 530. The configurations of the printed circuit board 510, the capacitor 520, the solder pads 521 and 522, and the slit 530 of FIGS. 15 to 17 may be identical in whole or part to the configuration of the printed circuit board 510, the capacitor 320, the solder pads 321 and 322, and the slit 350 of FIGS. 5 to 14. The structure of FIGS. 15 to 17 may be selectively combinable with the structures of FIGS. 5 to 14.

According to one or more embodiments, the printed circuit board 510 may be a printed circuit board 510 including a plurality of layers. The printed circuit board 510 may have a structure in which a plurality of insulation layers 511 (e.g., 511a, 511b, 511c, and 511d) and a plurality of conductive layers 512 (e.g., 512a, 512b, 512c, and 512d) are alternately stacked. For example, each of the conductive layers 512a, 512b, 512c, and 512d included in the plurality of conductive layers 512 may be disposed between the insulation layers 511a, 511b, 511c, and 511d included in the plurality of insulation layers 511.

According to one or more embodiments, e.g., the printed circuit board 510 may include a first conductive layer 512a, a first insulation layer 511a disposed on the first conductive layer 512a, a second conductive layer 512b disposed on the first insulation layer 511a, and a second insulation layer 511b disposed on the second conductive layer 512b. According to one or more embodiments, the printed circuit board 510 may include a third conductive layer 512c disposed on the second insulation layer 511b, a third insulation layer 511c disposed on the third conductive layer 512c, a fourth conductive layer 512d disposed on the third insulation layer 511c, or a fourth insulation layer 511d disposed on the fourth conductive layer 512d.

According to one or more embodiments, the first conductive layer 512a may include at least one slit layer 530a formed in an area adjacent to the capacitor 520 in the X-axis and/or Y-axis direction. For example, when the printed circuit board 510 is viewed from the upper side (+Z-axis direction), the first slit layer 530a may be formed in the first conductive layer 512a to overlap an area adjacent to the capacitor 520. According to one or more embodiments, the second conductive layer 512b may include at least one second slit layer 530b formed in an area adjacent to the capacitor 520 in the X-axis and/or Y-axis direction. For example, when the printed circuit board 510 is viewed from the upper side (+Z-axis direction), the second slit layer 530b may be formed in the second conductive layer 512b to overlap an area adjacent to the capacitor 520. According to one or more embodiments, the third conductive layer 512c may include a third slit layer 530c formed in an area adjacent to the capacitor 520 in the X-axis and/or Y-axis direction. For example, when the printed circuit board 510 is viewed from the upper side (+Z-axis direction), the third slit layer 530c may be formed in the third conductive layer 512c to overlap an area adjacent to the capacitor 520. According to one or more embodiments, the fourth conductive layer 512d may include at least one fourth slit layer 530d formed in an area adjacent to the capacitor 520 in the X-axis and/or Y-axis direction. For example, when the printed circuit board 510 is viewed from the upper side (+Z-axis direction), the fourth slit layer 530d may be formed in the fourth conductive layer 512d to overlap an area adjacent to the capacitor 520.

According to one or more embodiments, the first slit layer 530a may include at least one slit formed in an area adjacent to the capacitor 520 in the X-axis and/or Y-axis direction. For example, the first slit layer 530a may include at least one first-layer first slit 5301a (e.g., the first slit 331 of FIG. 6) disposed in the left direction (−X direction, first direction) of the capacitor 320. For example, the first slit layer 530a may include at least one first-layer second slit 5302a (e.g., the second slit 332 of FIG. 6) disposed in the right direction (+X direction, second direction) of the capacitor 320. For example, the first slit layer 530a may include at least one first-layer third slit 5303a (e.g., the third slit 333 of FIG. 6) disposed in at least one of the front direction (+Y direction, third direction), the rear direction (−Y direction, fourth direction), and the lower direction (−Z direction, fifth direction) of the capacitor 320.

According to one or more embodiments, the second slit layer 530b may include at least one slit formed in an area adjacent to the capacitor 520 in the X-axis and/or Y-axis direction. For example, the second slit layer 530b may include at least one second-layer first slit 5301b (e.g., the first slit 331 of FIG. 6) disposed in the left direction (−X direction, first direction) of the capacitor 320. For example, the second slit layer 530b may include at least one second-layer second slit 5302b (e.g., the second slit 332 of FIG. 6) disposed in the right direction (+X direction, second direction) of the capacitor 320. For example, the second slit layer 530b may include at least one second-layer third slit 5303b (e.g., the third slit 333 of FIG. 6) disposed in at least one of the front direction (+Y direction, third direction), the rear direction (−Y direction, fourth direction), and the lower direction (−Z direction, fifth direction) of the capacitor 320.

According to one or more embodiments, the third slit layer 530c may include at least one slit formed in an area adjacent to the capacitor 520 in the X-axis and/or Y-axis direction. For example, the third slit layer 530c may include at least one third-layer first slit 5301c (e.g., the first slit 331 of FIG. 6) disposed in the left direction (−X direction, first direction) of the capacitor 320. For example, the third slit layer 530c may include at least one third-layer second slit 5302c (e.g., the second slit 332 of FIG. 6) disposed in the right direction (+X direction, second direction) of the capacitor 320. For example, the third slit layer 530c may include at least one third-layer third slit 5303c (e.g., the third slit 333 of FIG. 6) disposed in at least one of the front direction (+Y direction, third direction), the rear direction (−Y direction, fourth direction), and the lower direction (−Z direction, fifth direction) of the capacitor 320.

According to one or more embodiments, the fourth slit layer 530d may include at least one slit formed in an area adjacent to the capacitor 520 in the X-axis and/or Y-axis direction. For example, the fourth slit layer 530d may include at least one fourth-layer first slit 5301d (e.g., the first slit 331 of FIG. 6) disposed in the left direction (−X direction, first direction) of the capacitor 320. For example, the fourth slit layer 530d may include at least one fourth-layer second slit 5302d (e.g., the second slit 332 of FIG. 6) disposed in the right direction (+X direction, second direction) of the capacitor 320. For example, the fourth slit layer 530d may include at least one fourth-layer third slit 5303d (e.g., the third slit 333 of FIG. 6) disposed in at least one of the front direction (+Y direction, third direction), the rear direction (−Y direction, fourth direction), and the lower direction (−Z direction, fifth direction) of the capacitor 320.

According to one or more embodiments, the first-layer first slit 5301a, the second-layer first slit 5301b, the third-layer first slit 5301c, and the fourth-layer first slit 5301d may be disposed to at least partially overlap in the Z-axis direction. According to one or more embodiments, the first-layer second slit 5302a, the second-layer second slit 5302b, the third-layer second slit 5302c, and the fourth-layer second slit 5302d may be disposed to at least partially overlap in the Z-axis direction. According to one or more embodiments, the first-layer third slit 5303a, the second-layer third slit 5303b, the third-layer third slit 5303c, and the fourth-layer third slit 5303d may be disposed to at least partially overlap in the Z-axis direction.

According to one or more embodiments, the first slit layer 530a and the second slit layer 530b, the third slit layer 530c, and/or the fourth slit layer 530d may include slits having substantially the same shape and/or arrangement. For example, the slits constituting the first slit layer 530a, the second slit layer 530b, the third slit layer 530c, and/or the fourth slit layer 530d may be formed in substantially the same shape. According to one or more embodiments, the first slit layer 530a, the second slit layer 530b, the third slit layer 530c, and/or the fourth slit layer 530d may include slits having different shapes and/or arrangements.

According to one or more embodiments, the lengths of the slits overlapping in the Z-axis direction among the slits constituting the first slit layer 530a, the second slit layer 530b, the third slit layer 530c, and/or the fourth slit layer 530d may be substantially the same. For example, referring to FIG. 15, the lengths in the X-axis direction of the first-layer third slit 5303a of the first slit layer 530a, the second-layer third slit 5303b of the second slit layer 530b, the third-layer third slit 5303c of the third slit layer 530c, and the fourth-layer third slit 5303d of the fourth slit layer 530d which overlap in the Z-axis direction may be a first length d1. The first length d1 may be shorter than the length of the capacitor 520 in the X-axis direction.

According to one or more embodiments, the lengths of the slits overlapping in the Z-axis direction among the slits constituting the first slit layer 530a, the second slit layer 530b, the third slit layer 530c, and/or the fourth slit layer 530d may be different from each other. For example, referring to FIG. 16, the length in the X-axis direction of the first-layer third slit 5303a of the first slit layer 530a may be a second length d2. The second length d2 may be substantially identical or similar to the length of the capacitor 520 in the X-axis direction. For example, there may be a plurality of second-layer third slits 5303b of the second slit layer 530b. There may be a plurality of second-layer third slits 5303b of the second slit layer 530b which are arranged at regular intervals in the X-axis direction. Each of the lengths in the X-axis direction of the plurality of second-layer third slits 5303b may be a third length d3. The lengths of the plurality of second-layer third slits 5303b in the X-axis direction may be substantially identical to or different from each other. The total length in the X-axis direction of the plurality of second-layer third slits 5303b arranged at regular intervals in the X-axis direction may be substantially identical to the second length d2. For example, the length in the X-axis direction of the third-layer third slit 5303c of the third slit layer 530c may be a fourth length d4. The fourth length d4 may be substantially identical or similar to the length of the capacitor 520 in the X-axis direction. The fourth length d4 may be substantially identical or similar to the second length d2. For example, the length in the X-axis direction of the fourth-layer third slit 5303d of the fourth slit layer 530d may be a fifth length d5. The fifth length d5 may be shorter than the length of the capacitor 520 in the X-axis direction. The fifth length d5 may be substantially identical or similar to the third length d3. The configuration, structure, and arrangement of the slits are not limited to the above-described embodiments, and may be variously changed in design, and may be variously combined in consideration of the size of the printed circuit board and the performance of the capacitor.

According to one or more embodiments, referring to FIG. 17, a slit may not be disposed in the lower direction (−Z direction, fifth direction) of the capacitor 520. For example, in the first slit layer 530a, the second slit layer 530b, the third slit layer 530c, and/or the fourth slit layer 530d, no slit may be disposed in the lower direction (−Z direction, fifth direction) of the capacitor 320. For example, the first slit layer 530a may include at least one first-layer first slit 5301a (e.g., the first slit 331 of FIG. 6) disposed in the left direction (−X direction, first direction) of the capacitor 320. For example, the first slit layer 530a may include at least one first-layer second slit 5302a (e.g., the second slit 332 of FIG. 6) disposed in the right direction (+X direction, second direction) of the capacitor 320. For example, the second slit layer 530b may include at least one second-layer first slit 5301b (e.g., the first slit 331 of FIG. 6) disposed in the left direction (−X direction, first direction) of the capacitor 320. For example, the second slit layer 530b may include at least one second-layer second slit 5302b (e.g., the second slit 332 of FIG. 6) disposed in the right direction (+X direction, second direction) of the capacitor 320. For example, the third slit layer 530c may include at least one third-layer first slit 5301c (e.g., the first slit 331 of FIG. 6) disposed in the left direction (−X direction, first direction) of the capacitor 320. For example, the third slit layer 530c may include at least one third-layer second slit 5302c (e.g., the second slit 332 of FIG. 6) disposed in the right direction (+X direction, second direction) of the capacitor 320. For example, the fourth slit layer 530d may include at least one fourth-layer first slit 5301d (e.g., the first slit 331 of FIG. 6) disposed in the left direction (−X direction, first direction) of the capacitor 320. For example, the fourth slit layer 530d may include at least one fourth-layer second slit 5302d (e.g., the second slit 332 of FIG. 6) disposed in the right direction (+X direction, second direction) of the capacitor 320.

An electronic device according to one or more embodiments of the disclosure may comprise a printed circuit board (e.g., the printed circuit board 310 of FIG. 5) and a capacitor (e.g., the capacitor 320 of FIG. 6) disposed on the printed circuit board. The printed circuit board may include a conductive layer (e.g., the conductive layer 312 of FIG. 5) including at least one slit (e.g., the slit 330 of FIG. 5) formed in an area adjacent to the capacitor and an insulation layer (e.g., the insulation layer 311 of FIG. 5) disposed on the conductive layer and including a portion (e.g., the portion 340 of FIG. 5) disposed in the at least one slit. At least one slit may be disposed adjacent to at least one side surface of the capacitor and spaced apart from the at least one side surface of the capacitor by a first distance (e.g., the first distance d1 of FIG. 9) or less. The slit may not be disposed to overlap under the capacitor.

According to one or more embodiments, the capacitor may be a multi-layer ceramic capacitor (MLCC).

According to one or more embodiments, the capacitor may include side surfaces including a first side surface facing in a first direction (−X direction), a second side surface facing in a second direction (+X direction) opposite to the first direction, a third side surface facing in a third direction (+Y direction) perpendicular to the second direction, and a fourth side surface facing in a fourth direction (−Y direction) opposite to the third direction, a lower surface disposed perpendicular to the side surfaces and facing in a lower direction (−Z direction) toward the printed circuit board, and an upper surface facing in an upper direction (+Z direction) opposite to the lower direction.

According to one or more embodiments, the electronic device may further comprise at least one solder pad (e.g., the solder pads 321 and 322 of FIG. 8) disposed between the capacitor and the printed circuit board.

According to one or more embodiments, the at least one solder pad may include a first solder pad (e.g., the first solder pad 321 of FIG. 8) attached to the lower surface of the capacitor in the first direction (i.e. on a first direction side of the lower surface) and a second solder pad (e.g., the second solder pad 322 of FIG. 8) attached to the lower surface of the capacitor in the second direction (i.e. on a second direction side of the lower surface).

According to one or more embodiments, the at least one slit may be formed to be recessed downward from one surface of the conductive layer contacting the insulation layer.

According to one or more embodiments, a thickness of the at least one slit may be smaller than or equal to a thickness of the conductive layer.

According to one or more embodiments, the at least one slit may include a first slit (e.g., the first slit 331 of FIG. 8) disposed parallel to the first side surface of the capacitor and a third slit (e.g., the third slit 333 of FIG. 8) disposed perpendicular to the first slit and disposed parallel to the third side surface of the capacitor.

According to one or more embodiments, the at least one slit may include a first edge parallel to an adjacent side surface among the at least one side surface of the capacitor and having a second length (e.g., the second length d2 of FIG. 9) and a second edge extending perpendicular to the first edge and having a third length (e.g., the third length d3 of FIG. 9). The second length may be two or more times larger than a length of the adjacent side surface among the at least one side surface of the capacitor.

According to one or more embodiments, the at least one slit may include a first slit (e.g., the first slit 331 of FIG. 8) disposed to the first direction of the capacitor and disposed adjacent to the first side surface and a second slit (e.g., the second slit 332 of FIG. 8) disposed to the second direction of the capacitor and disposed adjacent to the second side surface.

According to one or more embodiments, the at least one slit may include a third slit (e.g., the third slit 333 of FIG. 8) disposed to the third direction of the capacitor and disposed adjacent to the third side surface and a fourth slit (e.g., the fourth slit 334 of FIG. 8) disposed to the fourth direction of the capacitor and disposed adjacent to the fourth side surface.

According to one or more embodiments, the at least one slit may include a fifth slit (e.g., the fifth slit 335 of FIG. 8) disposed to face the lower surface of the capacitor.

According to one or more embodiments, the first length may be 0.2 mm or less.

According to one or more embodiments, the portion may protrude in the lower direction and be formed to fill the slit.

According to one or more embodiments, the at least one slit (e.g., 430 of FIG. 13) may include a first portion (e.g., 431 of FIG. 13) disposed to the third direction of the capacitor and disposed parallel to the third side surface, a second portion (e.g., 432 of FIG. 13) disposed to the fourth direction of the capacitor and disposed parallel to the fourth side surface, and a third portion (e.g., 433 of FIG. 13) connected perpendicularly to the first portion and the second portion and disposed to face the lower surface of the capacitor.

An electronic device according to one or more embodiments of the disclosure may comprise a printed circuit board (e.g., 510 of FIG. 15) and a capacitor (e.g., 520 of FIG. 15) disposed on the printed circuit board. The printed circuit board may include a first conductive layer (e.g., 512a of FIG. 15) including a first slit layer (e.g., 530a of FIG. 15) formed in an area adjacent to the capacitor, a first insulation layer (e.g., 511a of FIG. 15) disposed on the first conductive layer and including a first portion (340) disposed in the first slit layer, a second conductive layer (e.g., 512b of FIG. 15) disposed on the first insulation layer and including a second slit layer (e.g., 530b of FIG. 15) formed in the area adjacent to the capacitor, and a second insulation layer (e.g., 511b of FIG. 15) disposed on the second conductive layer and including a second portion 340 disposed in the second slit layer. A slit constituting the first slit layer and the second slit layer may be disposed adjacent to at least one side surface of the capacitor and spaced apart from the at least one side surface of the capacitor by a first distance (e.g., d1 of FIG. 15) or less.

According to one or more embodiments, the capacitor may be a multi-layer ceramic capacitor (MLCC).

According to one or more embodiments, at least one slit constituting the first slit layer may be substantially the same as a slit constituting the second slit layer.

According to one or more embodiments, a slit constituting the first slit layer may be different from a slit constituting the second slit layer.

According to one or more embodiments, the first slit layer and the second slit layer may include at least one of a first slit 331 disposed to the first direction of the capacitor and disposed adjacent to the first side surface, a second slit 332 disposed to the second direction of the capacitor and disposed adjacent to the second side surface, a third slit 333 disposed to the third direction of the capacitor and disposed adjacent to the third side surface, a fourth slit 334 disposed to the fourth direction of the capacitor and disposed adjacent to the fourth side surface, and a fifth slit 335 disposed to face the lower surface of the capacitor.

An electronic device according to one or more embodiments of the disclosure may comprise a printed circuit board and a capacitor disposed on the printed circuit board. The printed circuit board may include a conductive layer including at least one slit formed in an area adjacent to the capacitor and an insulation layer disposed on the conductive layer and including a portion disposed in the at least one slit. The at least one slit may be disposed adjacent to at least one side surface of the capacitor and spaced apart from the at least one side surface of the capacitor by a first distance or less. The slit may not be disposed to overlap under the capacitor.

According to one or more embodiments, the at least one slit may include one surface of a second length, extending parallel to the at least one side surface of the capacitor, and the second length may be at least 1.4 times longer than a length of the at least one side surface of the capacitor.

According to one or more embodiments, the at least one slit may include a first slit extending in the third direction and disposed adjacent to the first side surface and a second slit extending in the third direction and disposed adjacent to the second side surface.

According to one or more embodiments, the at least one slit may include a third slit extending in the first direction and disposed adjacent to the third side surface and a fourth slit extending in the first direction and disposed adjacent to the fourth side surface.

When charging and/or discharging the capacitor (e.g., 320 of FIG. 6) (MLCC) used in the electronic device, vibration may occur due to contraction and expansion of the capacitor (MLCC). The vibration of the capacitor (MLCC) may be delivered to the printed circuit board 310, so that the printed circuit board (e.g., 310 of FIG. 6) may vibrate, causing noise in an audible frequency band.

In the printed circuit board according to the disclosure, a change in the stacked structure allows the vibration energy of the capacitor to be attenuated while passing through the printed circuit board having heterogeneous media with different densities, thereby reducing the noise in an audible frequency band.

What is claimed is:

1. An electronic device comprising:
a printed circuit board; and
a capacitor on the printed circuit board,
wherein the printed circuit board comprises:
a conductive layer comprising at least one slit in an area adjacent to the capacitor; and
an insulation layer directly on the conductive layer and comprising a portion in the at least one slit,
wherein the at least one slit is parallel to at least one side surface of the capacitor, and is spaced apart from the at least one side surface of the capacitor by a first distance or less, and
wherein the at least one slit does not overlap the capacitor when viewed from above.

2. The electronic device of claim 1, wherein the at least one slit comprises one side having a second length extending parallel to the at least one side surface of the capacitor, and
wherein the second length is at least 1.4 times longer than a length of the at least one side surface of the capacitor.

3. The electronic device of claim 1, wherein the capacitor is a multilayer ceramic capacitor (MLCC).

4. The electronic device of claim 1, wherein the at least one side surface of the capacitor comprises:
a first side surface facing a first direction,
a second side surface facing a second direction opposite to the first direction,
a third side surface facing a third direction perpendicular to the first direction and the second direction, and
a fourth side surface facing a fourth direction opposite to the third direction.

5. The electronic device of claim 4, further comprising:
at least one solder pad between the capacitor and the printed circuit board,
wherein the at least one solder pad comprises a first solder pad coupled to a first direction side of a lower surface of the capacitor and a second solder pad coupled to a second direction side of the lower surface of the capacitor.

6. The electronic device of claim 1, wherein the at least one slit is recessed downward from one surface of the conductive layer contacting the insulation layer.

7. The electronic device of claim 1, wherein a thickness of the at least one slit is less than or equal to a thickness of the conductive layer.

8. The electronic device of claim 4, wherein the at least one slit comprises:
a first slit parallel to the first side of the capacitor, and
a third slit perpendicular to the first slit and parallel to the third side surface of the capacitor.

9. The electronic device of claim 1, wherein the at least one slit comprises:
a first side of a second length parallel to an adjacent side of the at least one side surface of the capacitor, and
a second side of a third length extending perpendicular to the first side, and
wherein the second length is at least twice a length of an adjacent side of the at least one side surface of the capacitor.

10. The electronic device of claim 4, wherein the at least one slit comprises:
a first slit adjacent to the first side surface and extending in the third direction, and
a second slit adjacent to the second side surface and extending in the third direction.

11. The electronic device of claim 10, wherein the at least one slit further comprises:
a third slit adjacent to the third side surface, and extending in the first direction, and
a fourth slit adjacent to the fourth side surface, and extending in the first direction.

12. The electronic device of claim 11, wherein the at least one slit comprises a fifth slit facing a lower surface of the capacitor.

13. The electronic device of claim 1, wherein the first distance is 0.2 mm or less.

14. The electronic device of claim 3, wherein the portion protrudes downward and fills the at least one slit.

15. The electronic device of claim 4, wherein the at least one slit comprises:
a first portion at the third side of the capacitor and parallel to the third side,
a second portion at the fourth side of the capacitor and parallel to the fourth side, and
a third portion connected to the first portion and the second portion and facing a lower surface of the capacitor.

16. An electronic device comprising:
a printed circuit board; and
a capacitor on the printed circuit board,
wherein the printed circuit board comprises:
a first conductive layer comprising a first slit layer in an area adjacent to the capacitor;
a first insulation layer on the first conductive layer and comprising a first portion in the first slit layer;
a second conductive layer on the first insulation layer and comprising a second slit layer in the area adjacent to the capacitor; and
a second insulation layer on the second conductive layer and comprising a second portion in the second slit layer, and
wherein a slit in the first slit layer and the second slit layer is adjacent to at least one side surface of the capacitor and spaced apart from the at least one side surface of the capacitor by a first distance or less.

17. The electronic device of claim 16, wherein the capacitor is a multi-layer ceramic capacitor (MLCC).

18. The electronic device of claim 16, wherein the slit comprises at least one slit in the first slit layer and a slit in the second slit layer.

19. The electronic device of claim 16, wherein the slit comprises a slit in the first slit layer and a slit in the second slit layer having a shape different than the slit in the first slit layer.

20. The electronic device of claim 16, wherein the first slit layer and the second slit layer include at least one of:
a first slit at a first side surface of the capacitor and adjacent to the first side surface,
a second slit at a the second side surface of the capacitor and adjacent to the second side surface,
a third slit at a third side surface of the capacitor and adjacent to the third side surface,
a fourth slit at a fourth side surface of the capacitor and adjacent to the fourth side surface, and
a fifth slit facing a lower surface of the capacitor.
